(19) United States
(12) Patent Application Publication
(10) Pub. No.: US 2021/0005252 A1
(43) Pub. Date: Jan. 7, 2021

(54) CROSS POINT DEVICE AND STORAGE APPARATUS

(71) Applicant: SONY SEMICONDUCTOR SOLUTIONS CORPORATION, Kanagawa (JP)

(72) Inventors: Shuichiro YASUDA, Kanagawa (JP); Minoru IKARASHI, Tokyo (JP)

(73) Assignee: SONY SEMICONDUCTOR SOLUTIONS CORPORATION, Kanagawa (JP)

(21) Appl. No.: 16/968,662

(22) PCT Filed: Feb. 12, 2019
(86) PCT No.: PCT/JP2019/004860

§ 371 Date: Aug. 10, 2020

(30) Foreign Application Priority Data
Mar. 19, 2018 (JP) 2018-051357

(51) Int. Cl. G11C 13/00; H01L 21/8239

(52) U.S. Cl. CPC G11C 13/004; G11C 13/0069; G11C 2213/71; G11C 13/0004; H01L 21/8239; G11C 13/0038

(57) ABSTRACT

A cross point device according to an embodiment of the present disclosure includes a first electrode, a second electrode that is provided to be opposed to the first electrode, and a memory, a selector, and a resistor that are stacked between the first electrode and the second electrode. Of the resistor, a resistance value obtained through application of a negative voltage is lower than a resistance value obtained through application of a positive voltage.

### TECHNICAL FIELD

The present disclosure relates to a cross point device having a memory and a sele ctor between electrodes, and relates to a storage apparatus including this.

### BACKGROUND ART

In recent years, it has been expected to achieve capacity enlargement of a nonvolatile memory for data storage as represented by a resistance-change type memory such as a ReRAM (Resistance Random Access Memory) (registered trademark) or a PRAM (Phase-Change Random Access Memory) (registered trademark). Meanwhile, a cross-point type storage apparatus (memory cell array) in which a memory cell is provided at an intersection point (cross point) between intersecting wiring lines has been developed. For example, the memory cell has a configuration in which a memory and a switch for cell selection (selector) are stacked via an intermediate electrode.

In the cross-point type storage apparatus, a large wiring capacity and a large transistor junction capacity are added to the memory. This causes an unintended large current to flow in the memory when the selector turns into a low-resistance state. In particular, there is an issue that a resistance state of the memory is caused to vary when a Iaarge current flows at the time of reading the memory.

Generally, it is possible to solve this issue by devising an improvement in a circuit, which, however, results in an issue of a decrease in an area efficiency of the memory. Other than this, there is also an example of inserting a series resistance into the memory cell that is provided at the cross point (for example, see NPTL 1), which has an issue of a characteristic becoming unstable when a large amount of energy is required at the time of resetting.

### CITATION LIST

### Non-Patent Literature

NPTL 1: VLSI 2015, S.H. Jo et al

### SUMMARY OF THE INVENTION

Meanwhile, for a cross-point type storage apparatus, it is expected to enhance a repeating characteristic.

It is desirable to provide a cross point device and a storage apparatus that make it possible to enhance the repeating characteristic.

A cross point device according to an embodiment of the present disclosure includes a first electrode, a second electrode provided to be opposed to the first electrode, and a memory, a selector, and a resistor that are stacked between the first electrode and the second electrode. Of the resistor, a resistance value obtained through application of a negative voltage is lower than a resistance value obtained through application of a positive voltage.

A storage apparatus according to an embodiment of the present disclosure includes one or a plurality of first wiring lines that extends in one direction, one or a plurality of second wiring lines that extends in another direction and intersects with the first wiring lines, and one or a plurality of cross point devices, according to the embodiment of the present disclosure described above, that is provided at an intersection point between the first wiring line and the second wiring line.

In the cross point device according to the embodiment of the present disclosure and the storage apparatus according to the embodiment, the memory, the selector, and the resistor are stacked between the first electrode and the second electrode that are provided to be opposed to each other. The resistor described above has a characteristic that a resistance value obtained through application of a negative voltage is lower than a resistance value obtained through application of a positive voltage. This causes a decrease in a voltage necessary for a reset operation of the memory and makes it possible to reduce variation in an application voltage to the memory due to resistance variation.

In the cross point device according to the embodiment of the present disclosure and the storage apparatus according to the embodiment, along with the memory and the selector, a resistor of which a resistance value obtained through application of a negative voltage is lower than a resistance value obtained through application of a positive voltage is provided between the first electrode and the second electrode that are provided to be opposed to each other. This causes a decrease in the voltage necessary for the reset operation of the memory. Thus, this reduces variation in the application voltage to the memory due to resistance variation, and it becomes possible to enhance the repeating characteristic of the memory.

It is to be noted that the effects described here are not necessarily, imitative, and may be any effect described in the present disclosure.

### BRIEF DESCRIPTION OF THE DRAWINGS

FIG. 1 is a cross-sectional schematic diagram that illustrates an example of a configuration of a cross point device according to an embodiment of the present disclosure.

FIG. 2 is a cross-sectional schematic diagram that illustrates an example of a configuration of a memory illustrated in FIG. 1.

FIG. 3 is a cross-sectional schematic diagram that illustrates an example of a configuration of a switch illustrated in FIG. 1.

FIG. 4A is a current-voltage characteristics diagram that illustrates an example of a combination of materials included in a resistor illustrated in FIG. 1.

FIG. 4B is a current-voltage characteristics diagram that illustrates another example of the combination of materials included in the resistor illustrated in FIG. 1.

FIG. 4C is a current-voltage characteristics diagram that illustrates another example of the combination of materials included in the resistor illustrated in FIG. 1.

FIG. 4D is a current-voltage characteristics diagram that illustrates another example of the combination of materials included in the resistor illustrated in FIG. 1.

FIG. 4E is a current-voltage characteristics diagram that illustrates another example of the combination of materials included in the resistor illustrated in FIG. 1.

FIG. 4F is a current-voltage characteristics diagram that illustrates another example of the combination of materials included in the resistor illustrated in FIG. 1.

FIG. 4G is a current-voltage characteristics diagram that illustrates another example of the combination of materials included in the resistor illustrated in FIG. 1.

FIG. 5 is a cross-sectional schematic diagram that illustrates another example of the configuration of the cross point device according to the embodiment of the present disclosure.

FIG. 6 is a cross-sectional schematic diagram that illustrates another example of the configuration of the cross point device according to the embodiment of the present disclosure.

FIG. 7 is a cross-sectional schematic diagram that illustrates another example of the configuration of the cross point device according to the embodiment of the present disclosure.

FIG. 8 is a cross-sectional schematic diagram that illustrates another example of the configuration of the cross point device according to the embodiment of the present disclosure.

FIG. 9 is a diagram that illustrates an example of an overview configuration of a memory cell array according to the embodiment of the present disclosure.

FIG. 10 is a diagram that illustrates another example of the overview configuration of the memory cell array according to the embodiment of the present disclosure.

FIG. 11 is a cross-sectional schematic diagram that illustrates an example of a configuration of a switch according to Modification Example 1 of the present disclosure.

FIG. 12 is a diagram that illustrates an example of an overview configuration of a memory cell array in Modification Example 2 of the present disclosure.

FIG. 13 is a diagram that illustrates another example of the overview configuration of the memory cell array in Modification Example 2 of the present disclosure.

FIG. 14 is a diagram that illustrates another example of the overview configuration of the memory cell array in Modification Example 2 of the present disclosure.

FIG. 15 is a diagram that illustrates another example of the overview configuration of the memory cell array in Modification Example 2 of the present disclosure.

### MODES FOR CARRYING OUT THE INVENTION

In the following, an embodiment of the present disclosure is described in detail with reference to drawings. The following description is a specific example of the present disclosure, and the present disclosure is not limited to the following embodiment. in addition, the present disclosure is not limited to a position, size, and proportion, etc. of each component illustrated in each drawing. It is to be noted that the description is given in the following order,
1. Embodiment
   (an example of a cross point device in which along with a memory and a switch, a resistor of which a resistance value obtained through application of a positive voltage and a resistance value obtained through application of a negative voltage are different from each other is stacked)
1-1. Configuration of Cross Point Device
1-2. Configuration of Me Cell Array
1-3. Workings and Effects
2. Modification Example 1 (an example of a switch that includes, between a pair of electrodes, an n-type conductive layer with a p-type chalcogenide layer in between)
2-1. Configuration of Switch
2-2. Workings and Effects
3.Modification Example 2 (an example of a memory cell array having a three-dimensional structure)

### 1. Embodiment

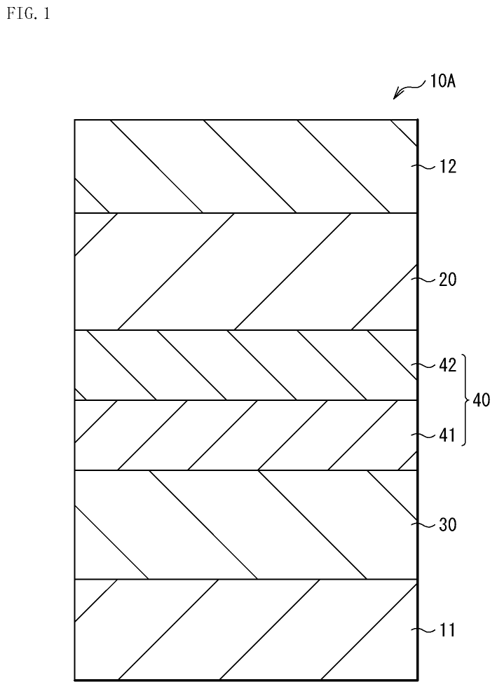

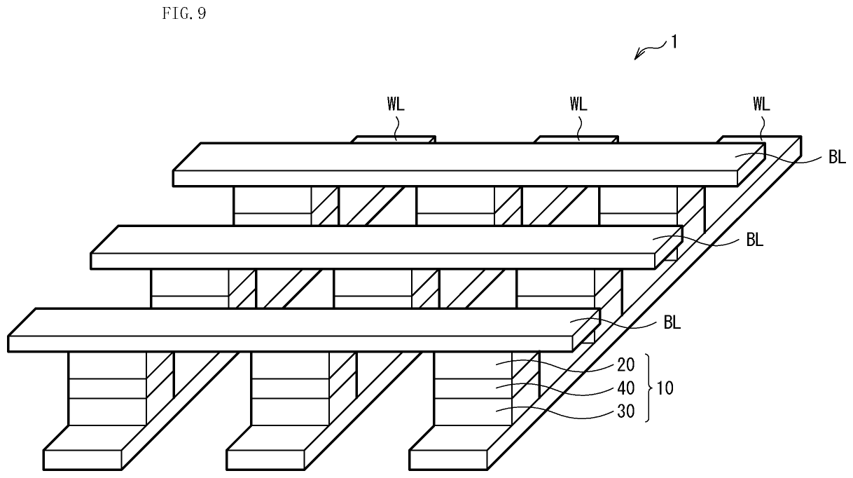

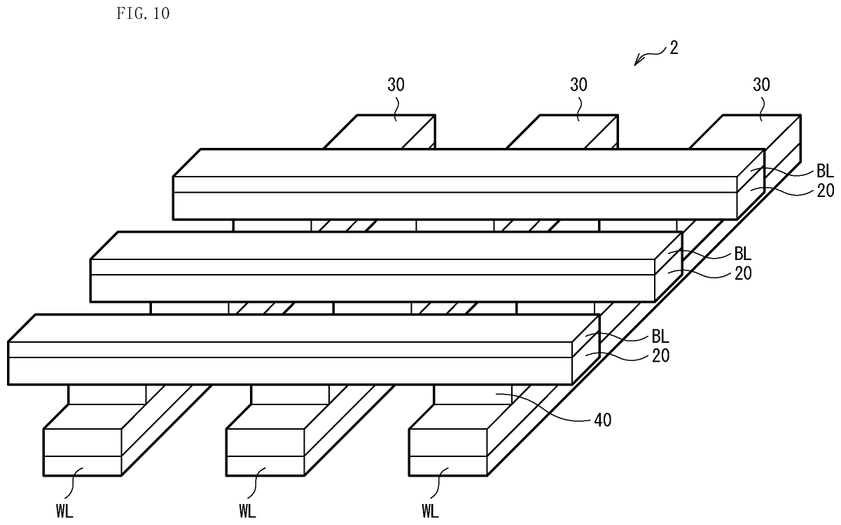

FIG. 1 illustrates an example of a cross-sectional configuration of a cross point device (cross point device 10) according to an embodiment of the present disclosure. For example, this cross point device 10 is provided, in a memory cell array 1 having what is called a cross-point array structure as illustrated in FIG. 9, at a position (cross point) at which a word line WL and a bit line BL that intersect with each other are opposed to each other. In the cross point device 10, between a lower electrode 11 (first electrode) and an upper electrode (second electrode) that are opposed to each other, for example, a switch 30, a resistor 40, and a memory 20 are stacked in this order. In the cross point device 10 according to the present embodiment, as the resistor 40, a resistor of which a resistance value obtained through application of a negative voltage is lower than a resistance value obtained through application of a positive voltage is used.

### (1-1. Configuration of Cross Point Device)

For example, the lower electrode 11 includes a wiring material used for a semiconductor process such as tungsten (W), tungsten nitride (WN), titanium nitride (TiN), copper (Cu), aluminum (Al), molybdenum (Mo), tantalum (Ta), tantalum nitride (TaN), or silicide. In a case where the lower lectrode 11 includes a material having a possibility of generating ionic conduction in an electric field, such as Cu, a surface of the lower electrode 11 that includes Cu or the like may be coated with a material that suppresses ionic conduction or thermal diffusion, such as W, WN, titanium nitride (TiN), or TaN.

As with the lower electrode 11, it is possible to use a publicly known semiconductor wiring material for an upper electrode 12. However, it is preferable to use, for example, a stable material that does not react with the memory 20 having direct contact with the material even after post annealing.

The memory 20 is a resistance-change type memory. In the memory 20, application of a voltage equal to or higher than a predetermined voltage between the lower electrode 11 and the upper electrode 12 causes a resistance state to switch to a low-resistance state, and the low-resistance state is recorded. In addition, application of a predetermined reverse voltage causes the low-resistance state to switch to a high-resistance state, and the high-resistance state is recorded. Here, the predetermined voltage is a voltage that allows obtaining of a predetermined writing resistance, and a resistance value that is to be written to the memory 20 varies with a change in a magnitude of a voltage or current to be applied.

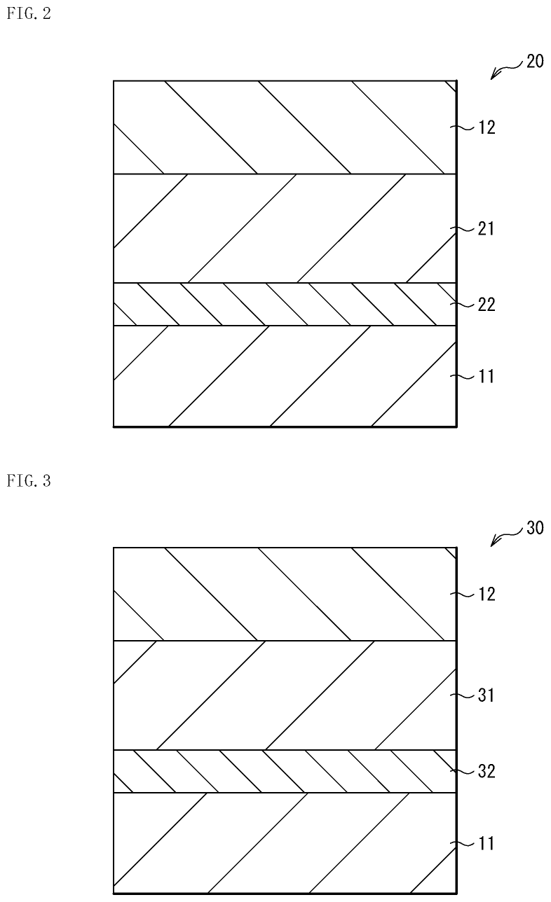

For example, as illustrated in FIG. 2, the memory 20 has a structure in which an ion source layer 21 and a variable resistance layer 22 are stacked between the lower electrode 11 and the upper electrode 12 that are provided to be opposed to each other.

The ion source layer 21 includes a movable element that moves into the variable resistance layer 22 as ions as a result of application of the electric field, to form a conduction path. For example, this movable element is a transition metal element, aluminum (Al), copper (Cu), or a chalcogen element. The chalcogen element, for example, includes tellurium (Te), selenium (Se), or sulfur (S). The transition metal element is a Group 4 to Group 6 element in the periodic table, and includes, for example, titanium (Ti), zirconium (Zr), hafnium (Hf), vanadium (V), niobium (Nb), tantalum (Ta), chromium (Cr), molybdenum (Mo), tungsten (W), or the like. The ion source layer 21 includes one type or two or more types of the movable elements described above. In addition, the ion source layer 21 may include oxygen (O), nitrogen (N), an element other than the movable elements described above (for example, manganese (Mn), cobalt (Co), iron (Fe), nickel (Ni), or platinum (Pt)), silicon (Si), or the like.

For example, the variable resistance layer 22 includes an oxide of a metallic element or nonmetallic element, or a nitride of a metallic element or nonmetallic element, and has a resistance value that varies in a case where a predetermined voltage is applied between the lower electrode 11 and the upper electrode 12. For example, when a voltage is applied between the lower electrode 11 and the upper electrode 12, the transition metal element included in the ion source layer 21 moves into the variable resistance layer 22 to form the conduction path, to thereby turn the variable resistance layer 22 into a low-resistance state. In addition, in the variable resistance layer 22, a structural defect such as an oxygen defect or a nitrogen defect is generated to form the conduction path, which turns the variable resistance layer 22 into the low-resistance state. In addition, as a result of application of a voltage reverse to a direction of the voltage applied when the variable resistance layer 22 turns into the low-resistance state, the conduction path is disconnected or variation in conductivity occurs, which turns the variable resistance layer 22 into the high-resistance state.

It is to be noted that the metallic element or nonmetallic element that is included in the variable resistance layer 22 need not necessarily be an oxide as a whole, and may be partially oxidized. In addition, for an initial resistance value of the variable resistance layer 22, for example, it is sufficient to achieve the memory having a resistance of about several MΩ to several hundred GΩ. Although an optimal value thereof also varies depending on a size of the memory or the resistance value of the ion source layer, it is preferable that the film thickness be about 1 nm to 10 nm, for example.

In addition, the memory 20 is not limited to the structure illustrated in FIG. 2. For example, the ion source layer 21 may be provided on the lower electrode 11 side, and the variable resistance layer 22 may be provided on the upper electrode 12 side. Furthermore, besides the ion source layer 21 and the variable resistance layer 22, another layer may be included.

The switch 30 is to selectively operate any memory 20 among a plurality of memories 20 provided at respective cross points in the memory cell array 1. The switch 30 is turned into the low-resistance state by increasing the application voltage to a level equal to or higher than a predetermined threshold voltage (switching threshold voltage), and is turned into the high-resistance state by decreasing the application voltage to a level lower than the threshold voltage (switching threshold voltage) described above. In other words, the switch 30 has a negative differential resistance characteristic, and causes a current that is several digit times larger to flow when the voltage applied to the switch 30 exceeds the predetermined threshold voltage. In addition, for the switch 30, an amorphous structure of the switch 30 is stably maintained irrespective of a voltage pulse or a current pulse being applied from an unillustrated power supply circuit (pulse application means)via the lower electrode 11 and the upper electrode 12. It is to be noted that the switch 30 does not perform a memory operation in which the conduction path formed as a result of ion movement due to voltage application is maintained even after erasing the application voltage, etc.

The switch 30 is coupled to the memory 20 in series and has a structure in which a switch layer 31 is provided between the lower electrode 11 and the upper electrode 12, for example.

The switch layer 31 includes a Group 16 element in the periodic table, which is, specifically, at least one type of chalcogen element selected from tellurium (Te), selenium (Se), and sulfur (S). In the switch 30 having an OTS (Ovonic Threshold Switch) phenomenon, it is necessary to stably maintain the amorphous structure of the switch layer 31 even when a bias voltage for switching is applied, and as the amorphous structure is more stable, it is possible to cause the OTS phenomenon more stably. The switch layer 31 includes, besides the chalcogen element described above, at least one type of element selected between boron (B) and carbon (C). In addition, the switch layer 31 further includes a Group 13 element in the periodic table excluding boron (B), which is, specifically, at least one type of element selected from aluminum (Al), gallium (Ga), and indium (In). The switch layer 31 further includes at least one type of element selected between phosphorus (P) and arsenic (As).

The switch 30 has a switching characteristic that the resistance value thereof is high in an initial state (high-resistance state (off-state)), and upon application of a voltage, the resistance value becomes low (low-resistance state (on-state)) at a certain voltage (switching threshold voltage). In addition, when the application voltage is decreased to a level lower than the switching threshold voltage or when the application of the voltage is stopped, the switch 30 returns to the high-resistance state, and the on-state is not maintained. In other words, the switch 30 does not perform the memory operation due to a phase change (between a non-crystalline phase (amorphous phase) and a crystalline phase) of the switch layer 31 being caused by the application of the voltage pulse or current pulse from an unillustrated power supply circuit (pulse application means)via the lower electrode 11 and the upper electrode 12.

It is to be noted that as illustrated in FIG. 3, for example, the switch 30 may have a configuration in which the switch layer 31 and a high-resistivity layer 32 are stacked. For example, the high-resistivity layer 32 has a higher insulation property than the switch layer 31 and includes, for example, an oxide or nitride of a metallic element or nonmetallic element, or a mixture of these. It is to be noted that FIG. 2 illustrates an example in which the high-resistivity layer 32 is provided on the lower electrode 11 side, but this is not limitative, and the high-resistivity layer 32 may be provided on the upper electrode 12 side. In addition, the high-resistivity layer 32 may be provided on both the lower electrode 11 side and the upper electrode 12 side with the switch layer 31 in between. Furthermore, the switch 30 may have a multilayer structure in which a plurality of sets of the switch layer 31 and the high-resistivity layer 32 are stacked.

The resistor 40 is to adjust, in the memory cell array 1, a current that flows between cross points of the word lines WL and the bit lines BL that intersect with each other. The resistor 40 used in the present embodiment has a resistance value that is different between when the positive voltage is applied between the lower electrode 11 and the upper electrode 12 and when the negative voltage is applied. Specifically, the resistor 40 has the characteristic that the resistance value obtained through application of the negative voltage is lower than the resistance value obtained through application of the positive voltage. It is to be noted that in the present embodiment, the positive voltage is a voltage at which the memory 20 tums into the low-resistance state as a result of the application, and the negative voltage is a voltage at which the memory 20 turns into the high-resistance state as a result of the application.

The resistor 40 is coupled to the memory 20 and the switch 30 in series, and is provided, as illustrated in FIG. 1, for example, between the memory 20 and the switch 30. The resistor 40 has a multilayer structure and is provided, as illustrated in in FIG. 1, for example, as a stack in which a first layer 41 and a second layer 42 are stacked in this order from the lower electrode 11 side, for example, It is preferable that the resistor 40 according to the present embodiment have a resistance per unit area of not less than 1E9 Ω/cm and 1E11 Ω/cm. The resistor 40 like this includes the following material, for example.

As described above, the resistor 40 has the characteristic that the resistance value obtained through application of the negative voltage is lower than the resistance value obtained through application of the positive voltage. To put it differently, a current that flows when the positive voltage is applied is smaller than a current that flows when the negative voltage is applied. In other words, the resistor 40 has a current-voltage characteristic having a positive-negative asymmetry.

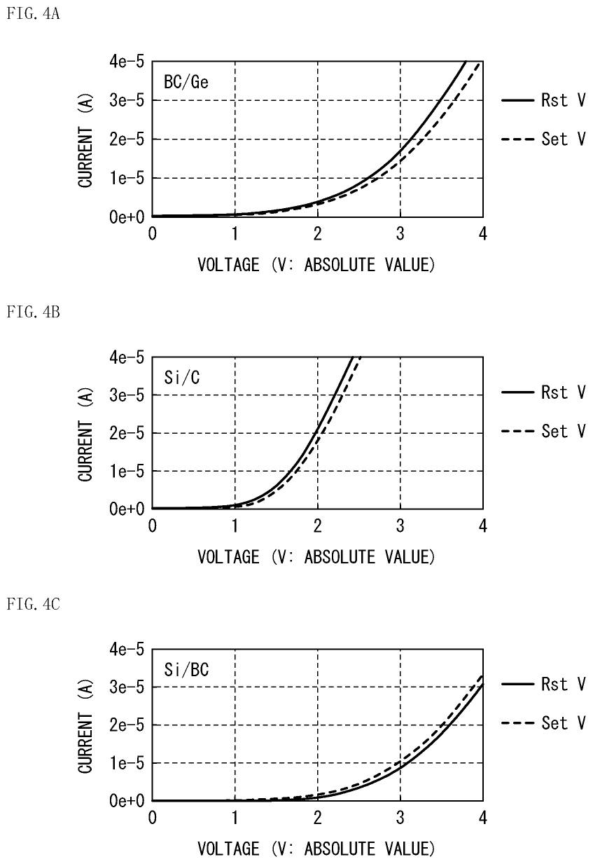

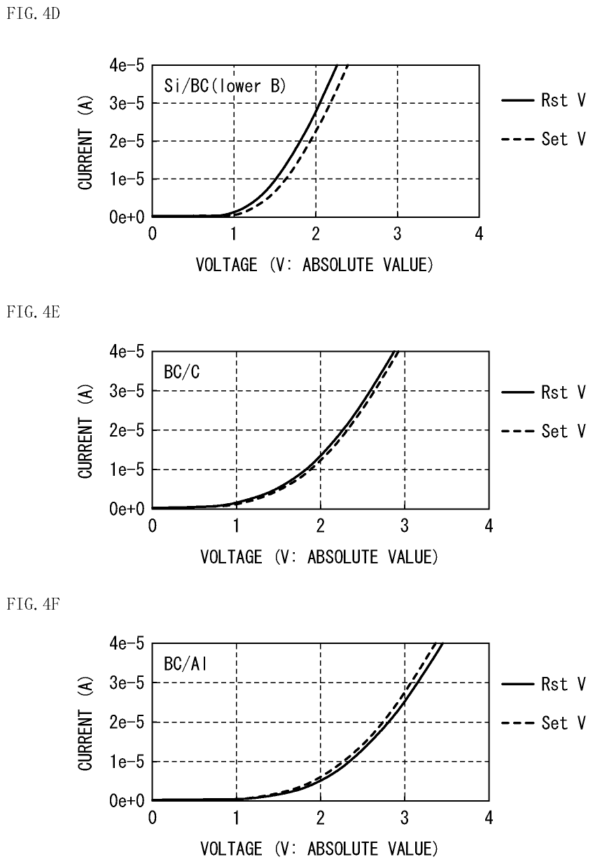

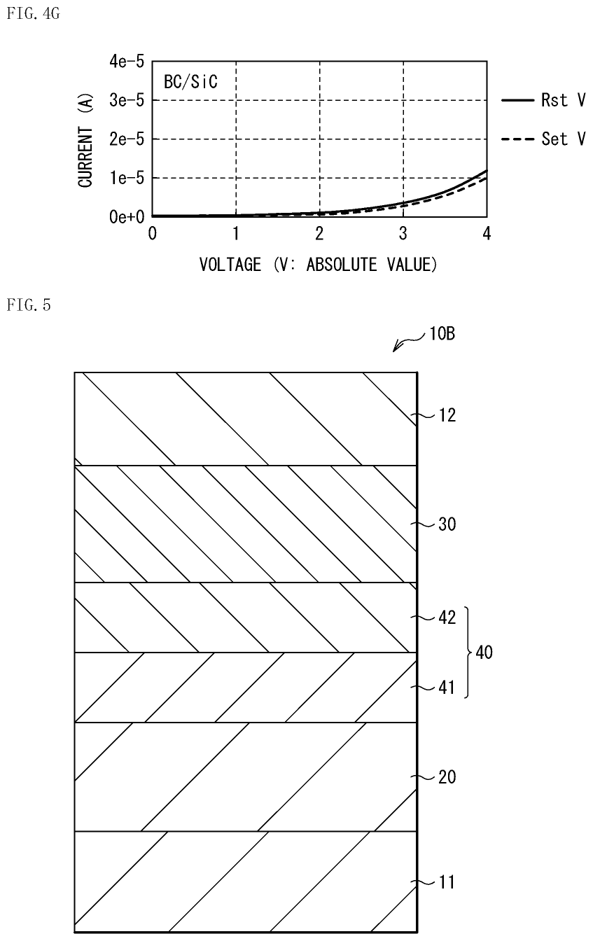

For example, it is preferable that the resistor 40 including a plurality of layers include, in one layer, at least one type of element from carbon (C), germanium (Ge), boron (B), and silicon (Si). FIGS. 4A to 4G each illustrate a current-voltage characteristic of a stacked film (here, two-layer film) that includes a combination of C, Ge, B, and Si, and aluminum (Al). As illustrated in FIGS. 4A to 4G, the stacked film in which on at least one side, a layer including C, Ge, B, and Si is provided and a layer having an elemental composition different from that of the one layer is stacked shows a behavior that is different between when the positive voltage (writing voltage (SetV)) is applied and when the negative voltage (erasing voltage (RstV)) is applied. Using this resistance difference makes it possible to form the resistor 40 with a current-voltage characteristic having positive-negative asymmetry. It is possible to amplify this asymmetry through a combination of layers as the first layer 41 and the second layer 42 that include a combination of two or more types of elements from carbon (C), germani (Ge), boron (B), and silicon (Si) to have elemental compositions different from each other. As an example, for example, in a case of increasing a resistance ratio, a ratio of B in C is increased, or a content of nitrogen (N) in C is increased, for example. In addition, the resistor 40 has a multilayer structure as described above, and for example, the resistor 40 having a five-layer structure of BC/Ge/Si/C/BC makes it possible to amplify the asymmetry.

For example, it is preferable that the first layer 41 and the second layer 42 each have a film thickness of not less than 1 nm and not more than 15 nm, in addition, for example, it is preferable that the resistance value of the first layer 41 and the second layer 42 be not less than 10 kΩ on a positive (+) side to reduce a damage that is likely to be applied from the wiring capacity. However, it is preferable that the resistance value be not more than 100 kΩ, for example, for the reason that an excessively high resistance value suppresses an operation of the memory 20, The resistance value on a negative (−) side is not particularly limitative, and the lower, the better.

It is to be noted that a desirable resistance range of the resistor 40 is defined by an operation condition of the memory cell array 1. For example, generally, the resistance-change type memory has an operation range of about 0.5 V to 2 V, and the switching threshold voltage for the switch to select the memory is 1 V to 4V. At the time of reading the resistance, after switching through a voltage application of 1 V to 4 V, the switch is in a state in which a voltage of about 0.5 V to 2 V is applied, and a remaining voltage of about 0.5 V to 2 V contributes to an electric discharge from the wiring capacity. Wiring resistance in a case where no measure is taken becomes around 1 kΩ, which causes a peak current of 500 μA to 2 mA to flow. Thus, to suppress the peak current to not more than 10 μA to 100 μA that is an operation current of the memory, it is preferable that the resistor 40 have a resistance value of 10 kΩ to 100 kΩ.

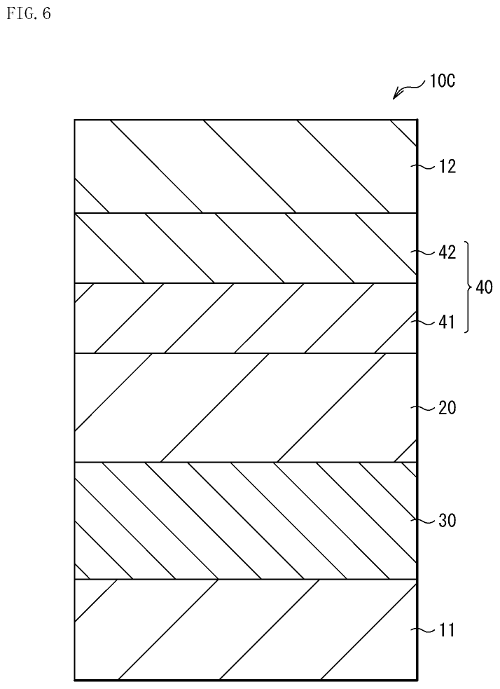

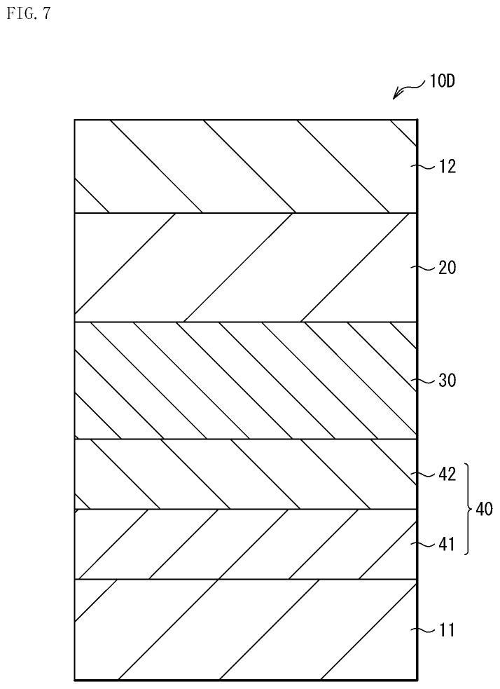

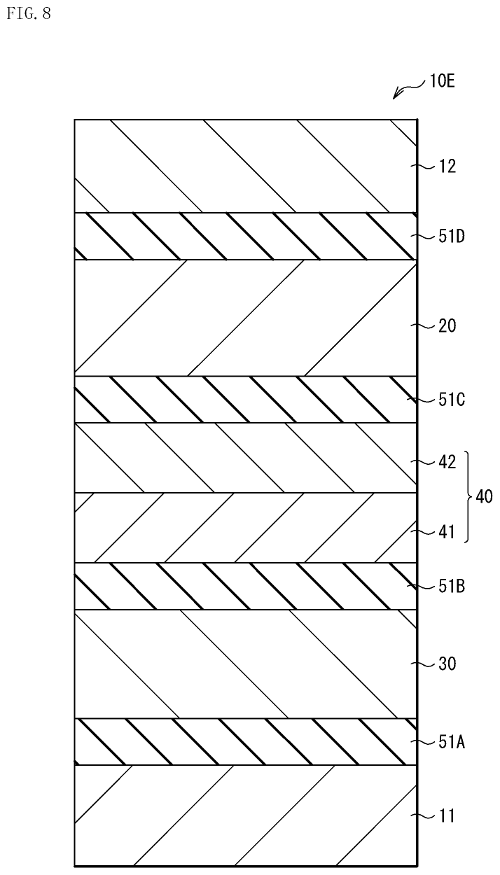

FIG. 1 illustrates, as a cross-sectional configuration of the cross point device 10, an example in which the switch 30, the resistor 40, and the memory 20 are stacked in this order between the lower electrode 11 and the upper electrode 12, but this is not limitative. For example, as illustrated in FIG. 5, the cross point device 10 may have a configuration in which the memory 20, the resistor 40, and the switch 30 are stacked in this order from the lower electrode 11 side. In addition, it is not entirely necessary to provide the resistor 40 between the memory 20 and the switch 30, and as illustrated in FIG. 6, for example, the cross point device 10 may have a configuration in which the switch 30, the memory 20, and the resistor 40 are stacked in this order from the lower electrode 11 side. Alternatively, as illustrated in FIG. 7, the cross point device 10 may have a configuration in which the resistor 40, the switch 30, and the memory 20 are stacked in this order from the lower electrode 11 side.

Furthermore, besides the memory 20, the switch 30, and the resistor 40, the cross point device 10 may include another layer between the lower electrode 11 and the upper electrode 12. For example, as illustrated in FIG. 8, other layers 51A, 51B, 51C, and 51D may be provided, respectively, between the lower electrode 11 and the switch 30, between the switch 30 and the resistor 40, between the resistor 40 and the memory 20, and between the memory 20 and the upper electrode 12. For example, the other layers 51A, 51B, 51C, and 51D may each be a metal film, and may include, for example, Ti, TiN, W, Ta, Ru, Al, or the like. In addition, for example, the other layers 51A, 51B, 51C, and 51D may each be a semiconductor film, and may include, for example, NiO, TiOx, TaOx, GaAs, CdTe, or the like.

### (1-2. Configuration of Memory Cell Array)

FIG. 9 perspectively illustrates an example of the configuration of the memory cell array (memory cell array 1) according to the present disclosure. The memory cell array 1 corresponds to a specific example of a “storage apparatus” according to the present disclosure. The memory cell array 1 includes what is called the cross-point array structure, and as illustrated in FIG. 2, for example, includes one memory cell for each position (cross point) at which each word line WL and each bit line BL are opposed to each other. In other words, the memory cell array 1 includes a plurality of word lines WL, a plurality of bit lines BL, and a plurality of memory cells provided at the respective cross points. In the memory cell array 1 according to the present embodiment, each memory cell includes the cross point device 10 described earlier, and a plurality of cross point devices 10 is provided on a plane (two-dimensionally, in an x-y plane direction).

Each word line WL extends in a direction common to each other. Each bit line BL extends in a direction that is different from an extension direction of the word line WL (for example, a direction orthogonal to the extension direction of the word line WL) and is common to each other. It is to be noted that the plurality of word lines WL is provided in one or a plurality of layers, and as illustrated in FIG. 12, for example, may be provided separately in a plurality of levels. The plurality of bit lines BL is provided in one or a plurality of layers, and as illustrated in FIG. 12, for example, may be provided separately in a plurality of levels.

The memory cell array 1 includes a plurality of cross point devices 10 that is provided two-dimensionally on a substrate. For example, the substrate has a group of wiring lines coupled electrically to each word line WL and each bit line BL, and a circuit, etc. to couple the group of wiring lines with an external circuit. Each word line WL and each bit line BL may double as the lower electrode 11 and the upper electrode 12 described earlier, or may be provided separately from the lower electrode 11 and the upper electrode 12. In this case, for example, the lower electrode 11 is electrically coupled to the word line WL, and the upper electrode 12 is electrically coupled to the bit line BL.

FIG. 10 perspectively illustrates another example of the configuration of the memory cell array (memory cell array 2) according to the present disclosure. As with the memory cell array 1 described above, this memory cell array 2 has what is called the cross-point array structure. In the memory cell array 2, the memory 20 extends along each bit line BL that extends in a direction common to each other. The switch 30 extends along the word line WL that extends in a direction different from the extension direction of the bit line BL (for example, a direction orthogonal to the extension direction of the bit line BL). In the configuration, for example, the resistor 40 is provided at the cross point between each of the plurality of word lines WL and each of the plurality of bit lines BL, and the memory 20 and the switch 30 are stacked via this resistor 40.

In this manner, providing a configuration in which the memory 20 and the switch 30 are provided not only at the cross point but also to extend in the extension direction of the word line WL and the extension direction of the bit line BL, respectively, makes it possible to deposit the switch layer or the memory layer, and a layer that is to be the bit line BL or the word line WL at the same time, thus allowing performance of collective shape processing using a photolithography process, Thus, it becomes possible to reduce the number of processing steps.

### (1-3. Workings and Effects)

As described earlier, in a cross-point type storage apparatus, a large wiring capacity and a large transistor junction capacity are added to the memory. This causes an unintended large current to flow in the memory when the selector turns into the low-resistance state. in particular, there is an issue that the resistance state of the memory is caused to vary when a large current flows at the time of reading the memory.

Generally, it is possible to solve this issue by devising an improvement in the circuit, which results in an issue of a decrease in area efficiency of the memory. Other than this, there is an example of inserting a series resistance into the memory cell that is provided at the cross point, which has an issue of a characteristic becoming unstable when a large amount of energy is required at the time of resetting.

For example, in a case of inserting the series resistance into the memory cell, the same current is able to flow at the time of setting and at the time of resetting. A general cross-point type storage apparatus switches a gate voltage of the transistor to cause a large amount of current to flow at the time of resetting. However, in the case of inserting the series resistance, an energy that is usable when applying the same reset voltage becomes smaller due to the resistance value loaded at the time of resetting, which prevents the memory from turning into a sufficiently high-resistance state. It is possible to increase the sable energy by increasing the reset voltage, but in this case, the characteristic of the memory is deteriorated due to another deterioration mode due to the application of a high voltage.

In contrast, in the cross point device 10 according to the present embodiment, between the lower electrode 11 and the upper electrode 12 that are provided to be opposed to each other, along with the memory 20 and the switch 30. the resistor 40 of which the resistance value obtained through application of the negative voltage is lower than the resistance value obtained through application of the positive voltage is provided in series.

A reset operation (erasing operation) of the memory 20 that is a resistance-change type memory is completed when a current equal to the current in a set operation (writing operation) is applied. One reason for this is that the equal current is necessary to return the ions that have moved to the variable resistance layer 22 at the time of writing. Therefore, in a case where the series resistance inserted into the cross point device 10 has a low resistance value, resetting is performed at a low application voltage, and in a case where the series resistance has a higher resistance value, resetting is performed at a high application voltage. It is known that a repeating characteristic is accelerated by variation in the application voltage to the memory due to the resistance variation at the time of resetting. In other words, when the series resistance is low, and as the voltage necessary for the reset operation is lower, the variation in the application voltage to the memory due to the resistance variation is smaller, which is advantageous for the repeating characteristic of the memory.

In the present embodiment, as described above, the resistor 40 of which the resistance value obtained through application of the negative voltage is lower than the resistance value obtained through application of the positive voltage is provided in series with respect to the memory 20 and the switch 30. This reduces the voltage necessary for the reset operation of the memory 20, which makes it possible to reduce the variation in the application voltage to the memory due to the resistance variation.

From the above, in the cross point device 10 and the memory cell array 1 according to the present embodiment, the resistor 40 of which the resistance value obtained through application of the negative voltage is lower than the resistance value obtained through application of the positive voltage is provided in series with respect to the memo 20 and the switch 30, and this is provided at the cross point between the word line WL and the bit line BL. This reduces the voltage necessary for the reset operation of the memory 20, and reduces the variation in the application voltage to the memory 20 due to the resistance variation. Thus, it becomes possible to enhance the repeating characteristic of the memory 20, and to enhance the repeating characteristic of the memory cell array 1 including this.

Next, modification examples (Modification Examples 1 and 2) of the above embodiment are described. In the following, the same reference numerals are assigned to components similar to those in the above embodiment, and descriptions thereof are omitted where appropriate.

### <2. Modification Example 1>

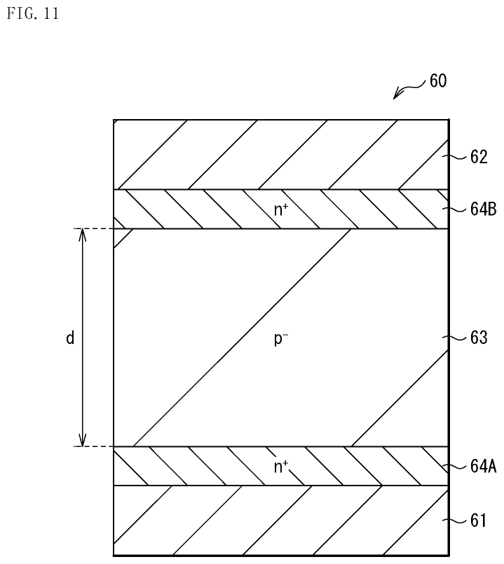

FIG. 11 illustrates an example of a cross-sectional configuration of a switch (switch 60) included in the cross point device 10 according to Modification Example 1 of the present disclosure. In this switch 60, a switch layer 63, and n-type conductive layers 64A and 64B that are provided on the lower electrode 61 side and the upper electrode 62 side are stacked between a lower electrode 61 and an upper electrode 62 that are provided to be opposed to each other.

### (2-1. Configuration of Switch)

For the lower electrode 61, it is preferable to use an electrode material that reacts with a semiconductor including a chalcogenide included in the switch layer 63 that is to be described later, and it is preferable to use carbon (C), for example. Other than this, for example, it is possible to use magnesium (Mg), aluminum (Al), zinc (Zn), tin (Sn), or the like.

As with the lower electrode 61, for the upper electrode 62, it is preferable to use an electrode material that reacts with the semiconductor including the chalcogenide included in the switch layer 63, and it is preferable to use carbon (C), for example. Other than this, for example, it is possible to use magnesium (Mg), aluminum (Al), zinc (Zn), tin (Sn), or the like.

For example, the switch layer 63 includes a Group 16 element in the periodic table excluding oxygen (O), which is, specifically, at least one type of chalcogen element selected from tellurium (Te), selenium (Se), and sulfur (S). The switch layer 63 includes, other than the chalcogen element described above, at least one type of element selected between boron (B) and carbon (C), for example. In addition, the switch layer 31 may further include a Group 13 element in the periodic table excluding boron (B), which is, specifically, at least one type of element selected from aluminum (Al), gallium (Ga), and indium (in). The switch layer 31 may further include at least one type of element selected from germanium (Ge), phosphorus (P), and arsenic (As). The switch layer 63 includes a semiconductor (chalcogenide semiconductor) including the above element along with the chalcogen element, and has a p-type conductivity.

The n-type conductive layers 64A and 64B are formed by injecting, into the switch layer 63, for example, nitrogen (N), phosphorus (P), arsenic (As), antimony (Sb), etc. as a dopant element. Alternatively, the n-type conductive layers 64A and 64B are formed as a result of the chalcogenide semiconductor included in the switch layer 63 being reduced by heating after deposition of the paper electrode 62 or by generation of Joule heat at the time of forming. Alternatively, it is preferable to form the n-type conductive layers 64A and 64B, using both methods. It is preferable that, for example, a heating temperature be a temperature appropriate for causing a reaction between carbon (C) included in the lower electrode 61 and the upper electrode 62 and the chalcogenide semiconductor and volatilizing a reactant thereof as gas. For example, as a substrate temperature, it is preferable to set a temperature range to a comparatively low temperature of not less than 400 K and not more than 700 K. It is to be noted that in a case of forming the n-type conductive layers 64A and 64B by heating, it is preferable to use sulfur (S) or selenium (Se) as the chalcogen element used for the switch layer 63.

For example, in a case of the switch layer 63 including Ge₂As₂Se, as a result of heating, etc. after deposition, Ge₂As₂Se generates 2GeAs and 3CSE₂ by an oxidation-reduction reaction with the lower electrode 61 and the upper electrode 62 each including C. 3CSE₂ has a melting point of −43.7° C., and turns into gas by heating to be removed from an interface between the switch layer 63 and eac4h of the lower electrode 61 and the upper electrode 62, and 2GeAs of the n-type remains. Thus, the n-type conductive layers 64A and 64B are provided at the interface between the switch layer 63 and each of the lower electrode 61 and the upper electrode 62.

For the n-type conductive layers 64A and 64B formed using the method described above, due to a sequence of deposition processes, the n-type conductive layer 64B having contact with the upper electrode 62 has higher controllability than the n-type conductive layer 64A having contact with the lower electrode 61, and has a lower resistance value ratio, Accordingly, the switch 60 has a current-voltage characteristic asymmetrical with respect to a voltage: application axis.

In the switch 60 according to the present modification example, inclusion of the re-type conductive layers 64A and 64B results in a decrease in a potential barrier at an electrode interface between the switch layer 63 and each of the lower electrode 61 and the upper electrode 62. On the other hand, the switch layer 63 sandwiched between the n-type conductive layer 64A and the n-type conductive layer 64B becomes depleted as a whole, which generates an internal barrier referred to as a built-in potential. It is preferable that a thickness d of the region occupied by the internal barrier be not less than 5 nm for the following reason. As the thickness of the depletion layer increases, a carrier injected into the depletion layer is accelerated by the electric field, to achieve a carrier-multiplication effect generally referred to as avalanche multiplication.

Assuming that a mean free path is λ, an elementary charge is e, and the electric field is F:, kinetic energy E of the carrier transiting in the depletion layer (a hole in a case of the p-type) is defined by Expression (1) below.

(Mathematical Expression 1)

E=λeF . . . (1)

To cause avalanche multiplication to occur, it is necessary that the kinetic energy E of the carrier exceed energy Ei that is necessary for causing impact ionization. A condition therefor is expressed by Expression (2) below.

(Mathematical Expression 2)

E>Ei . . . (2)

It is indicated that a minimum transit distance D to satisfy the condition (2) for the mean free path λ is approximately expressed by Expression (3) below (see Y. Okuto and C. R. Crowell, “Threshold energy effect on avalanche breakdown voltage in semiconductor junctions,” Solid-State Electronics, 18, 161 (1975)).

(Mathematical Expression 3)

D/λ>10 . . . (3)

In addition, a crystal semiconductor (for example, Si) has a mean free path of about 5 nm, while an amorphous semiconductor (for example, a-Si) has a mean free path that is about the same as an interatomic distance (about 0.5 nm in a c-axis direction). This shows that to satisfy Expression (3), it is necessary that a minimum film thickness be not less than 5 nm. Because the minimum transit distance is determined with reference to the interatomic distance, the minimum film thickness of the switch layer 63 is about 5 nm.

In a state in which avalanche multiplication is working, the threshold voltage constantly has a positive temperature coefficient with respect to an ambient temperature. Even if an internal resistance of the material itself of the depletion layer has a negative temperature coefficient, it is possible to offset the negative temperature coefficient by the positive temperature coefficient due to the avalanche multiplication. Thus, it is possible to independently adjust a threshold-voltage dependence of the switch 60 as a whole with respect to the ambient temperature.

### (2-2. Workings and Effects)

In most cases, the semiconductor (chalcogeni.de semiconductor) including a chalcogen element that is a Group 16 element in the periodic table excluding oxygen has the p-type type conductivity. When causing, as a material for a selective diode, the chalcogenide semiconductor to directly contact with an electrode, what is called a Schottky barrier is formed. An off characteristic of diode characteristics is determined by an ideality factor that is a time limit of a contact resistance and a height of the Schottky barrier, The ideality factor and the height of the Schottky harrier are each a physical quantity difficult to control even if a leading-edge semiconductor processing technique is applied, which makes it difficult to achieve mass production of the selective diode having a uniform electrical characteristic.

In contrast, the switch 60 according to the present modification example includes the n-type conductive layers 64A and 64B between the switch layer 63 including the chalcogenide semiconductor and having the p-type conductivity and each of the lower electrode 61 and the upper electrode 62. This makes it possible to reduce a Schottky barrier potential at the interface between each of the lower electrode 61 and the upper electrode 62 and the switch layer 63, and to form an internal barrier potential (built-in potential) having higher controllability than the Schottky barrier potential. Thus, it becomes possible to achieve mass production of the switch 60 having an operation condition with reduced unevenness. Furthermore, the switch layer 63 has a film thickness of not less than 5 nm to secure the film thickness of not less than 5 nm for the region occupied by the internal barrier (depletion layer). This causes the carrier injected into the depletion layer to be accelerated by the electric field, to achieve a carrier multiplication effect referred to as avalanche multiplication. This makes it possible to reduce a temperature dependence of the switching threshold voltage of the switch 60 with respect to the ambient temperature. Thus, it becomes possible to achieve the memory cell array 1 having a large scale and high reliability. In addition, it becomes unnecessary to provide a circuit as a measure for temperature compensation for the cross point device 10 in the memory cell array 1.

It is to be noted that, for example, stacking the switch 60 according to the present modification example directly with the resistor 40 using carbon (C) in the foregoing embodiment, for example, allows the layer including C in the resistor 40 to double as the n-type conductive layer 64A or the n-type conductive layer 64B. This makes it possible to reduce the total number of the cross point devices 10.

### <3. Modification Example 2>

It is possible to include the cross point device 10 according to the foregoing embodiment in a memory cell array having a three-dimensional structure. FIGS. 12 to 15 each perspectively illustrate an example of a configuration of a corresponding one of memory cell arrays 3 to 6 having a three-dimensional structure according to a modification example of the present disclosure. In the memory cell array having a three-dimensional structure, each word line WL extends in a direction common to each other. Each bit line BL extends in a direction that is different from the extension direction of the word line WL (for example, a direction orthogonal to the extension direction of the word line WL) and is common to each other. Furthermore, a plurality of word lines WL and a plurality of bit lines BL are provided in a plurality of layers separately.

In a case where the plurality of word lines WL is provided separately in a plurality of levels, the plurality of bit lines BL is provided in a layer between a first layer in which some of the word lines WL are provided and a second layer that is adjacent to the first layer and in which some of the word lines WL are provided. In a case where the plurality of bit lines BL is provided separately in a plurality of levels, the plurality of word lines WL is provided in a layer between a third layer in which some of the bit lines BL are provided and a fourth layer that is adjacent to the third layer and in which some of the bit lines BL are provided. In a case where the plurality of word lines WL is provided separately in a plurality of levels and the plurality of bit lines BL is provided separately in a plurality of levels, the plurality of word lines WL and the plurality of bit lines BL are alternately provided in a stacking direction of the memory cell array.

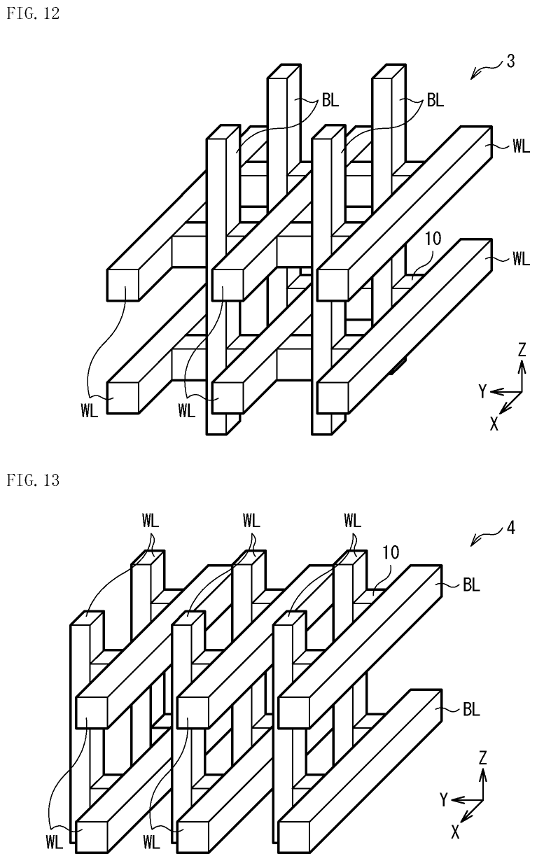

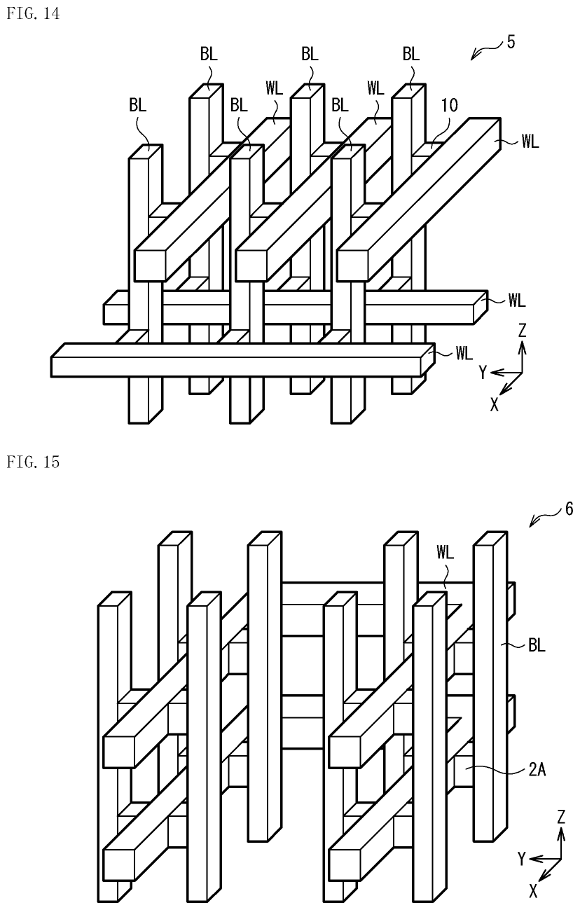

The memory cell array according to the present modification example has a vertical cross-point structure in which either the word lines WL or the bit lines BL are provided parallel to a z-axis direction, and the others are provided parallel to the x-y plane direction. For example, as illustrated in FIG. 12, the memory cell array may have a configuration in which each of the plurality of word lines WL extends in an x-axis direction, each of the plurality of bit lines BL extends in the z-axis direction, and the cross point device 10 is provided at each cross point. In addition, as illustrated in FIG. 13, the memory cell array may have a configuration in which the cross point device 10 is provided on both sides of the cross point between each of the plurality of word lines WL and each of the plurality of bit lines BL that extend, respectively, in the x-axis direction and the z-axis direction. Furthermore, as illustrated in FIG. 14, the memory cell array may have a configuration in which the plurality of bit lines BL extends in the z-axis direction and two types of the plurality of word lines WL extend in either one of two directions, that is, the x-axis direction or a y-axis direction. Furthermore, it is not entirely necessary that the plurality of word lines WL and the plurality of bit lines BL each extend in one direction. For example, as illustrated in FIG. 15, for example, the plurality of bit lines BL may extend in the z-axis direction, and the plurality of word lines WL may extend in the x-axis direction and bend in the middle in the y-axis direction, and further bend in the x-axis direction, to extend in what is called a U-shape on the x-y plane.

As described above, the memory cell array according to the present disclosure, as a result of having a three-dimensional structure in which a plurality of cross point devices 10 is provided on a plane (two-dimensionally, in the x-y plane direction) and further stacked in the z-axis direction, makes it possible to provide a storage apparatus having a higher density and a larger capacity.

The present disclosure has been described above with reference to the embodiment and Modification Examples 1 and 2, but the content of the present disclosure is not limited to the above embodiment, etc., and various modifications are possible. For example, for an operation method of the memory cell array (for example, the memory cell array 1using the cross point device 10 according to the present disclosure, it is possible to use various biasing schemes such as a publicly known V or V/2 scheme, or V or V/3 scheme.

In addition, in Modification Example 1 described above, an example has been illustrated in which the n-type conductive layers 64A and 64B are provided, respectively, between the lower electrode 61 and the switch layer 63, and between the switch layer 63 and the upper electrode 62, but providing the n-type conductive layer in at least one side makes it possible to obtain the effect in the present Modification Example 1.

It is to be noted that the effects described in the present specification are merely examples. The effects of the present disclosure are not limited to those described in the present specification. The content of the present disclosure may have any effect other than the effects described in the present specification.

In addition, for example, the present disclosure may have the following configurations.

(1)

A cross point device, including:

a first electrode;

a second electrode provided to be opposed to the first electrode; and

a memory, a selector, and a resistor that are stacked between the first electrode and second electrode, in which

of the resistor, a resistance value obtained through application of a negative voltage is lower than a resistance value obtained through application of a positive voltage,

(2)

The cross point device according to (1), in which

the positive voltage is a voltage at which the memory turns into a low-resistance state as a result of the application, and the negative voltage is a voltage at which the memory turns into a high-resistance state as a result of the application.

(3)

The cross point device according to (1) or (2), in which

the resistor has a resistance per unit area of not less than 1E9Ω/cm and 1E11 Ω/cm.

(4)

The cross point device according to any one of (1) to (3), in which

the resistor has a multilayer structure, the resistor including, in at least one layer of the multilayer structure, at least one of carbon (C), germanium. (Ge), boron (B), or silicon (Si).

(5)

The cross point device according to any one of (1) to (4), in which

the memory and the selector are stacked in this order between the first electrode and the second electrode, and

the resistor is provided at least one of between the first electrode and the memory, between the memory and the selector, or between the selector and the second electrode.

(6)

The cross point device according to (5), in which

the selector includes a switch layer and an n-type conductive layer, the switch layer having a p-type conductivity and including a chalcogenide semiconductor, the n-type conductive layer being provided at least one of between the switch layer and the first electrode or between the switch layer and the second electrode, and the switch layer includes a depletion layer having a film thickness of not less than 5 nm.

(7)

The cross point device according to (6), in which

the second electrode includes carbon (C).

(8)

The cross point device according to (6) or (7), in which

the resistor doubles as the n-type conductive layer.

(9)

The cross point device according to any one of (1) to (8), in which

the memory, upon application of a voltage between the first electrode and the second electrode, switches a resistance state at a voltage not less than a predetermined voltage and records a low-resistance state, and records a high-resistance state upon application of a voltage reverse to the predetermined voltage.

(10)

The cross point device according to any one of (1) to (9), in which

the selector, without causing a phase change between a non-crystalline phase and a crystalline phase, is turned into a low-resistance state by making an application voltage not less than a predetermined threshold voltage, and is turned into a high-resistance state by making the application voltage lower than the threshold voltage.

(11)

A storage apparatus, including

one or a plurality of first wiring lines that extends in one direction;

one or a plurality of second wiring lines that extends in another direction and intersects with the one or plurality of first wiring lines; and

one or a plurality of cross point devices each provided at an intersection point between each of the one or plurality of first wiring lines and each of the one or plurality of second wiring lines, in which

the cross point device includes
a first electrode,
a second electrode provided to be opposed to the first electrode, and
a memory, a selector, and a resistor that are stacked between the first electrode and the second electrode, and

of the resistor, a resistance value obtained through application of a negative voltage is lower than a resistance value obtained through application of a positive voltage.

(12)

A cross point device, including:

a first electrode;

a second electrode provided to be opposed to the first electrode; and

a memory, a selector, and a resistor that are stacked between the first electrode and the second electrode, in which

the selector includes a switch layer and an n-type conductive layer, the switch layer having a p-type conductivity and including a chalcogenide semiconductor, the n-type conductive layer being provided at least one of between the switch layer and the first electrode or between the switch layer and the second electrode, and

the switch layer includes a depletion layer having a film thickness of not less than 5 nm.

The present application claims the priority on the basis of Japanese Patent Application No. 2018-051357 filed on Mar. 19, 2018 with Japan Patent Office, the entire contents of which are incorporated in the present application by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A cross point device, comprising:
a first electrode;
a second electrode provided to be opposed to the first electrode; and
a memory, a selector, and a resistor that are stacked between the first electrode and the second electrode, wherein
of the resistor, a resistance value obtained through application of a negative voltage is lower than a resistance value obtained through application of a positive voltage.

2. The cross point device according to claim 1, wherein
the positive voltage is a voltage at which the memory turns into a low-resistance state as a result of the application, and the negative voltage is a voltage at which the memory turns into a high-resistance state as a result of the application.

3. The cross point device according to claim 1, wherein
the resistor has a resistance per unit area of not less than 1E9 Ω/cm and 1E11 Ω/cm.

4. The cross point device according to claim 1, wherein
the resistor has a multilayer structure, the resistor including, in at least one layer of the multilayer structure, at least one of carbon (C), germanium (Ge), boron (B), or silicon (Si).

5. The cross point device according to claim 1, wherein
the memory and the selector are stacked in this order between the first electrode and the second electrode, and
the resistor is provided at least one of between the first electrode and the memory, between the memory and the selector, or between the selector and the second electrode.

6. The cross point device according to claim 5, wherein
the selector includes a switch layer and an n-type conductive layer, the switch layer having a p-type conductivity and including a chalcogenide semiconductor, the n-type conductive layer being provided at least one of between the switch layer and the first electrode or between the switch layer and the second electrode, and
the switch layer includes a depletion layer having a film thickness of not less than 5 nm.

7. The cross point device according to claim 6, wherein
the second electrode includes carbon (C).

8. The cross point device according to claim 6, wherein
the resistor doubles as the n-type conductive layer.

9. The cross point device according to claim 1, wherein
the memory, upon application of a voltage between the first electrode and the second electrode, switches a resistance state at a voltage not less than a predetermined voltage and records a low-resistance state, and records a high-resistance state upon application of a voltage reverse to the predetermined voltage.

10. The cross point device according to claim 1, wherein
the selector, without causing a phase change between a non-crystalline phase and a crystalline phase, is turned into a low-resistance state by making an application voltage not less than a predetermined threshold voltage, and is turned into a high-resistance state by making the application voltage lower than the threshold voltage.

11. A storage apparatus, comprising:
one or a plurality of first wiring lines that extends in one direction;
one or a plurality of second wiring lines that extends in another direction and intersects with the one or plurality of first wiring lines; and
one or a plurality of cross point devices each provided at an intersection point between each of the one or plurality of first wiring lines and each of the one or plurality of second wiring lines, wherein
the cross point device includes
a first electrode,
a second electrode provided to be opposed to the first electrode, and
a memory, a selector, and a resistor that are stacked between the first electrode and the second electrode, and
of the resistor, a resistance value obtained through application of a negative voltage is lower than a resistance value obtained through application of a positive voltage.
